(19) United States
(12) Patent Application Publication
(10) Pub. No.: US 2025/0068061 A1
(43) Pub. Date: Feb. 27, 2025

(54) Nano-Grid Scalable Fabrication

(71) Applicant: Authentix, Inc., Addison, TX (US)

(72) Inventors: Milad Khoshnegar Shahrestani, Coquitlam (CA); Ruifeng Yang, Oakville (CA); Clay Schultz, New Westminister (CA); Huawei Li, Vancouver (CA)

(21) Appl. No.: 18/676,401

(22) Filed: May 28, 2024

Related U.S. Application Data
(60) Provisional application No. 63/469,351, filed on May 26, 2023.

(51) Int. Cl. G03F 7/00

(52) U.S. Cl. CPC G03F 7/0002

(57) ABSTRACT

A patterned composite material and a method for forming the material is disclosed. In one example, the method includes making a copy mold having a patterned mold surface, metallizing elevated structures and trenches, and removing caps from the structure to create the patterned composite material.

### CROSS REFERENCE TO RELATED APPLICATION

This application claims the benefit under 35 U.S.C. § 119(e) from U.S. Provisional Application No. 63/469,351, entitled “Nano-Grid Scalable Fabrication,” filed on May 26, 2023. The entirety of the disclosure of the foregoing document is incorporated herein by reference.

### TECHNICAL FIELD

The present invention is in the field of nanotechnology, and more specifically, to grid nanostructures and methods for forming grid nanostructures.

### BACKGROUND INFORMATION

Conductive nanowire grids (e.g., nano-grids) have a range of applications in automotive and near-eye displays as heaters (e.g., de-icing, or de-foging), 5G/6G communication systems (e.g., electromagnetic wave deflectors, or transparent antennas), or EMI shielding. The millimiter wave transmission/reflection characteristics of nano-grids depend on structural properties of the grid, including, but not limited to, material, width and height of the wires, and periodicity of the grid. These parameters contribute to the conductivity/resistance of the wires and therefore the grid, and thus impact transmission, reflection, and absorption properties of the grid. Creating deterministically positioned nanowires is feasible using lithography techniques and the dimensions of the nanowires play a role in deciding what lithography process is suitable for wafer-scale and high-volume production of nano-grids. Nanowires larger than a few microns wide can be patterned using photolithography, deep ultraviolet (UV) lithography, or laser lithography, for example. Fabrication of sub-micron nanowires may use deep UV lithography or electron beam lithography to resolve the narrow width of the wires.

Although many of the applications listed above can involve sheets of conductive nanowire grids that have a footprint of at least one square meter (m²), the high-resolution production methods capable of making nanowire grids can typically handle nano-grid footprints of only up to several inches in diameter and are not suited for high volume production. Some of them, such as direct laser lithography, may reach footprints of up to m², however, they typically offer limited resolution and the production throughput is relatively low.

The conductivity and sheet resistance of the nano-grid pattern also depends on the quality of the conductive layer. Thin film metals, transparent conductors (such as indium tin oxide (ITO)), and conductive inks are among the existing candidates suitable for nano-patterned conductive grids. The application process of a conductive coating for patterning into a nano-grid should, however, be roll-to-roll (R2R) or roll-to-plate (R2P) compatible vacuum deposition or printing in order to fulfil high-throughput volume production requirements.

Thus, what is needed are methods for producing large sheets of nano-grids composed of sub-micron nanowires that utilize R2R, R2P, or plate-to-plate (P2P) production methods.

### SUMMARY

It has been discovered that certain combinations of surface patterning, deposition, and transfer processes can be combined to fabricate patterned composite materials including networks of nanowires. This discovery has been exploited to develop the present disclosure, which, in part, is directed to methods of fabricating patterned composite materials that can be scaled to form large format sheets of the patterned composite materials.

In one novel aspect, a patterned composite material structure comprises a substrate and an uncured resin layer. The substrate comprises a layer of cured resin material having a network of elevated structures separated by trenches. These trenches have electrically conductive material disposed on a bottom surface. The elevated structures have electrically conductive material disposed on a top surface of the elevated structures such that a portion of the conductive material on the top surface of the elevated structures extends partially over the trenches. The uncured resin layer is disposed to contact the electrically conductive material in the trenches and sidewalls of the elevated structures and enclose the electrically conductive material on the elevated structures.

Further details and embodiments and methods and techniques are described in the detailed description below. This summary does not purport to define the invention. The invention is defined by the claims.

### DESCRIPTION OF THE DRAWINGS

The foregoing and other objects of the present disclosure, the various features thereof, as well as the disclosure itself may be more fully understood from the following description, when read together with the accompanying drawings:

FIG. 1 is a schematic representation of a periodic nano-grid structure made according to the disclosure.

FIG. 2A is a flow chart representation of an example a method for forming a patterned composite material according to the disclosure.

FIG. 2B is a schematic representation of the manufacturing method of nano-grid EM director using nanoimprint lithography (NIL) process according to the disclosure.

FIG. 3 is a diagrammatic representation of the conductive nano-grid produced in the process of FIG. 2A according to the disclosure.

FIC. 4 is a diagrammatic representation of two implementations of the nano-grid, which can be ridges (top) or trenches (bottom) according to the disclosure.

FIG. 5 is a diagrammatic representation of the nano-peeling mechanism in the ridge embodiments shown in FIG. 4 according to the disclosure.

FIG. 6 is a diagrammatic representation of the nano-peeling mechanism in the trench embodiment shown in FIG. 4 according to the disclosure.

FIG. 6B is a diagram that shows how the viscosity of the encapsulating layer may help an easier nano-peeling process when the base resin and the encapsulating resin have different viscosity and adhesion to the conductive layer.

FIG. 7 is a schematic representation of a simplified roll-to-roll setup for the implementing nano-peeling step according to the disclosure.

FIG. 8 is a schematic representation of a simplified roll-to-plate setup for implementing another nano-peeling step according to the disclosure.

FIG. 9 is a representation of a photograph of an example transparent nano-grid layer against a window according to the disclosure. The nano-grid layer is the conductive metal grid and does not include the encompassing polymers/resin.

FIG. 10A is a representation of a scanning electron micrograph of an example of a bi-layer conductive material according to the disclosure.

FIG. 10B is a representation of a scanning electron micrograph of an example nano-grid conductive layer before and after the nano-peeling process according to the disclosure.

### DETAILED DESCRIPTION

The disclosures of these patents, patent applications, and publications in their entireties are hereby incorporated by reference into this application in order to more fully describe the state of the art as known to those skilled therein as of the date of the invention described and claimed herein. The instant disclosure will govern in the instance that there is any inconsistency between the patents, patent applications, and publications and this disclosure.

Unless defined otherwise, all technical and scientific terms used herein have the same meaning as commonly understood by one of ordinary skill in the art to which this disclosure belongs. The initial definition provided for a group or term herein applies to that group or term throughout the present specification individually or as part of another group, unless otherwise indicated.

For the purposes of explaining the invention, well-known features of nanoimprinting technology known to those skilled in the art of nanoprinting have been omitted or simplified in order not to obscure the basic principles of the invention. Parts of the following description will be presented using terminology commonly employed by those skilled in the art of optical design.

As used herein, the articles “a” and “an” refer to one or to more than one (i.e., to at least one) of the grammatical object of the article. By way of example, “an element” means one element or more than one element. Furthermore, use of the term “including” as well as other forms, such as “include,” “includes,” and “included,” is not limiting.

As used herein, the term “about” will be understood by persons of ordinary skill in the art and will vary to some extent on the context in which it is used. As used herein, when referring to a measurable value such as an amount, a temporal duration, and the like, the term “about” is meant to encompass variations of ±20% or ±10%, including ±5%, ±1%, and ±0.1% from the specified value, as such variations are appropriate to perform the disclosed methods.

As used herein, the term “transparent” refers to the physical property of a material that allows light to pass through the material without appreciable scattering of the light. Generally, a transparent object will allow one to see objects clearly on the other side of it. In some examples, a transparent object will transmit about 50% or more (e.g., about 80% or more, about 90% or more, about 95% or more, about 98% or more, about 99% or more) of normally incident light at an operative wavelength without appreciable scattering. In some cases, transparent is used interchangeably or synonymously with “mostly transparent” and “substantially transparent,” as no dielectric materials are 100% transparent.

For simplicity and clarity of illustration, reference numerals may be repeated among the figures to indicate corresponding or analogous elements. Numerous details are set forth to provide an understanding of the examples described herein. The examples may be practiced without these details. In other instances, well-known methods, procedures, and components have not been described in detail to avoid obscuring the examples described.

The present disclosure relates to roll-to-roll (R2R) and roll-to-plate (R2P) compatible nanoimprint-lithography-based methods which utilize nano-scale lamination and nano-peeling to produce conductive nano-grid structures. The method provides high-resolution patterning capabilities for realizing nano-grid structures and introduces minimal chemicals (no wet etching or lift-off or stripping) to the production process.

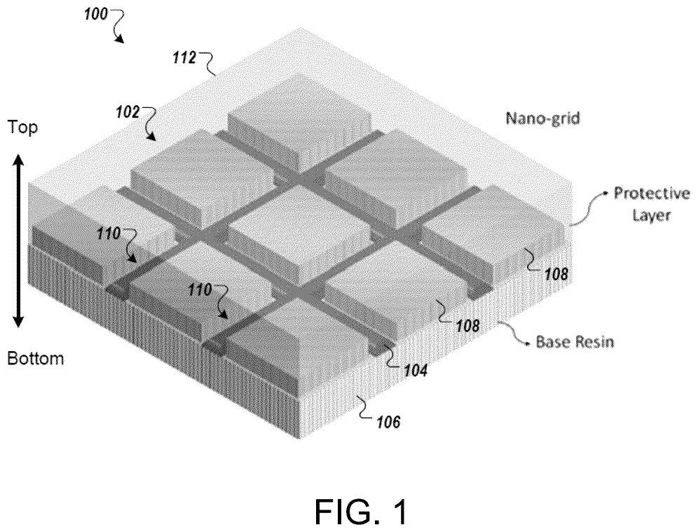

A portion of an exemplary nano-grid structure 100 having a periodic nano-grid 102 is shown in FIG. 1. The nano-grid 102 is composed of a periodic network of conductive nanowires 104 and elevated structures 108 formed on a transparent polymeric resin layer 106 (e.g., a photopolymer or thermoplastic). The resin layer 106 is patterned with a network of trenches 110 separated by elevated structures 108. The nanowires 104 reside in the trenches 108 and extend in a plane.

Reference is made to ‘top’ surfaces and ‘bottom’ surfaces. For case of reference, the nanowires 104 are located on a ‘top’ surface of the resin layer 106, e.g., a ‘bottom’ surface of the trenches 110. The opposite side of the resin layer is the ‘bottom’ surface. This terminology is adopted for other layers, where the top side or top surface faces the same way as the top surface of resin layer and the bottom side or bottom surface is opposite.

The base resin layer 106 includes a periodic array of elevated structures 108 extending by a height above the bottom surface of the trenches 110. Trenches 110 extend between the structures 108 and form a rectilinear square pattern, though other examples of trenches 110 are based on other geometries, such as rectangular, circular, semi-circular, pentagonal, hexagonal, or combinations thereof. Patterns that include curved or irregular trenches are also possible.

The width of the trenches 110 in the resin layer 106 is in a range from about 50 nm and about 10 microns (e.g., but not limited to, about 200 nm and about 2 microns, about 300 nm and about 800 nm). The height of the trenches 110 (e.g., the distance between the bottom of the trenches 110 and the upper surface of the elevated structures 108) is in a range from about 100 nm and about 5 microns (e.g., but not limited to, about 300 nm and about 2 microns, or about 400 nm and about 1 micron).

The nanowires 104 are conductive materials deposited on the bottom of the trenches 110. Said another way, the nanowires 104 are deposited in the trenches 110 between the structures 108. The nanowires 104 are composed of conductive metal (e.g., but not limited to, silver, copper, aluminum, gold, combinations or alloys thereof), conductive ink (e.g., but not limited to, carbon ink, or silver ink), or semi-conductors (e.g., but not limited to, indium tin oxide (ITO)).

The nanowires 104 have a thickness that is less than or equal to the height of the structures 108 and take up a portion of the total height of the trenches 110. In many examples, the nanowires 104 have a thickness of up to about 5 microns (e.g., but not limited to, up to about 4 microns, up to about 3 microns, up to about 2 microns, up to about 1 microns), or less than about 1 micron, and can depend on the height of the structures 108 in the resin layer 106 (e.g., but not limited to, about 50 nm to about 500 nm, or 100 nm to 200 nm).

An optically transparent and durable protective layer 112 covers the nano-grid 102 and provides protection from damaging contact or contamination (e.g., dust) to the nano-grid 102. Some examples of the protective layer 112 are made from polymer resin (similar to or difference from embossed/base resin), printable lacquer. It is preferably flexo or gravure compatible.

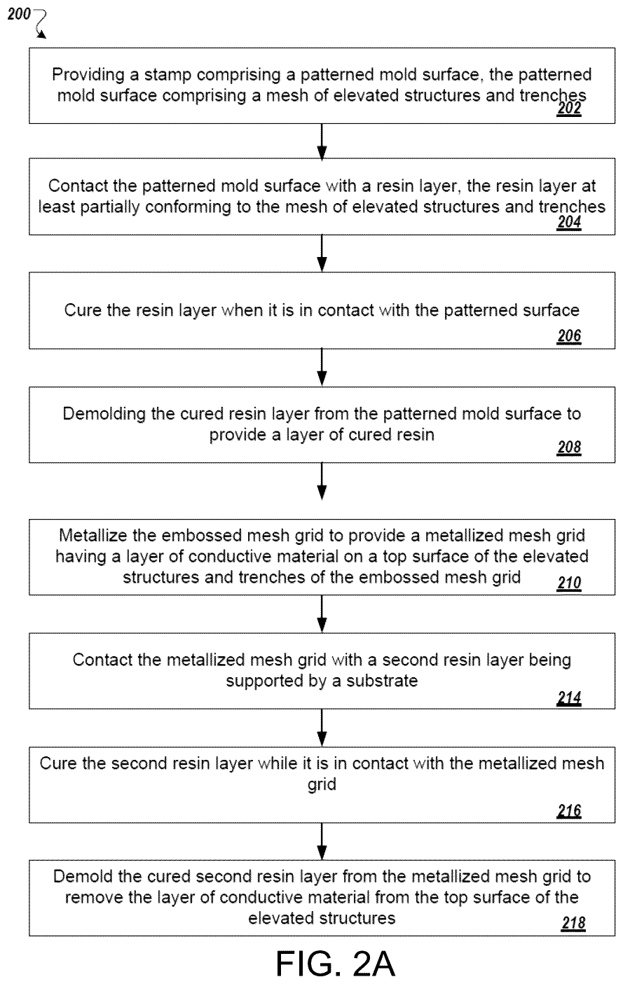

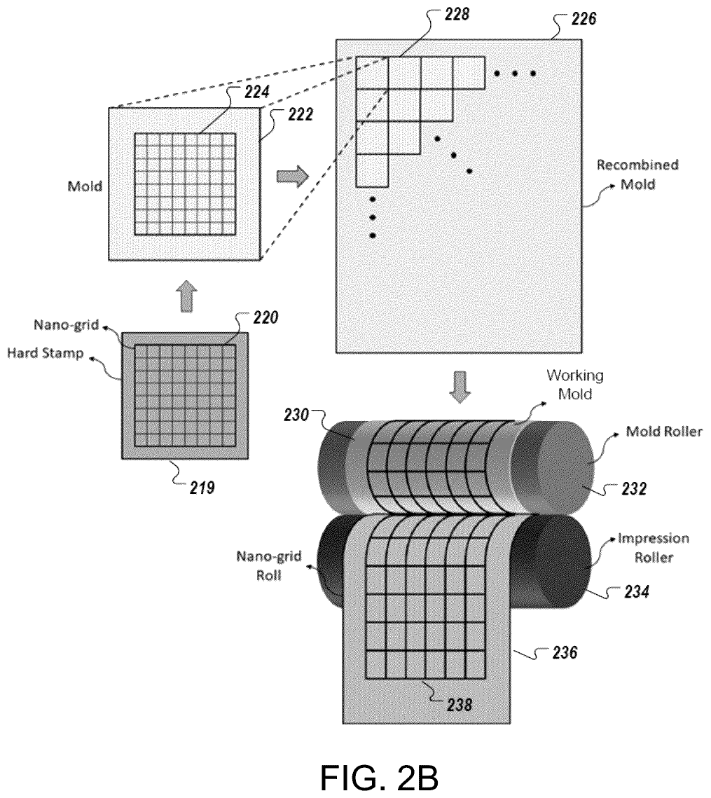

A method for producing the nano-grid structure 100 is provided herein and comprises the steps shown in a flow chart diagram in FIG. 2A and is schematically illustrated in FIG. 2B. In general, a hard stamp incorporating a patterned mold surface (e.g., ‘nano-grid’) of patterned features to be transferred to the substrate is provided. The ‘trenches’ or ‘ridges’ polarity to be copied to the substrate. The feature polarity of the patterned mold surface will be inverted after each replication step. Said another way, a pattern of trenches in the hard stamp will create a pattern of ridges, while a pattern of ridges in the hard stamp will create a pattern of trenches in the subsequent mold.

The features of the patterned mold surface can have one or more dimension in sub-micron size, or less than about 5 microns. The patterned mold surface is fabricated onto the hard stamp using high-resolution lithography, etching, deposition techniques, or a combination. In an example, roll-to-plate or plate-to-plate wafer-scale nanoimprint lithography (NIL) is used to make copy molds of the hard stamp on a similarly sized mold substrate. In general, the substrate can be flexible (e.g., but not limited to, certain plastics) or rigid (e.g., but not limited to, glass), transparent or opaque.

The mold substrate is used for the ‘place and repeat’ upscaling process. In the upscaling process, a larger-sized ‘recombined’ mold will be imprinted via a sequential place and repeat process, in which several positionally aligned imprints of the original mold are embossed onto a larger substrate. The recombined mold may then be used to produce flexible or hard imprints, using roll-to-roll (R2R) or roll-to-plate (R2P) NIL process, respectively.

The method 200 includes the following steps. A hard stamp 219 including a patterned mold surface 220, the patterned mold surface including a mesh of ridges and/or trenches is provided (202).

A hard stamp 219 is produced to create a nano-grid patterned mold surface 220 onto a non-flexible substrate such as silicon or quartz wafer coated with lithography resist. Electron beam lithography, photolithography, ion milling, direct laser writing, or similar processes are used to make features (e.g., trenches or ridges) on the substrate, the processes selected depending on the dimensions (e.g., width) of the features (e.g., grid lines).

A wafer may be used as a hard stamp 219 substrate depending on the desired size of the replicas. The wafer can made of any material that can be processed using lithography techniques, including a silicon wafer, a quartz wafer, glass, sapphire, or similar material. This wafer is coated with positive or negative electron beam resist, depending on the targeted polarity of ridges or trenches of the patterned mold surface 220 on the hard stamp 219. For example, a positive resist is used which and is removed after electron beam lithography and chemical development of the resist, leaving a patterned mold surface 220 of a nano-grid of trenches in the resist. The hard stamp 219 substrate then is plasma etched using the suitable chemistry to achieve the desired feature depth. The resist thickness may be changed based on the selectivity of the plasma etching process employed in the next step and based on the targeted depth of the grid lines of the patterned mold surface 220. Anisotropic etching with slightly tapered etch profile enabled by plasma etching is useful for the subsequent NIL replication steps. A positively tapered etch profile facilitates demolding with minimal structural damage to the nanostructures.

In another example, a dry plasma etching process with selectivity of at least 1 is used to produce trenches in the hard stamp 219. The selectivity is defined as the ratio between the etch rate of the substrate material and the etch rate of the resist mask, which depends on several parameters such as plasma density, gas chemistry, RF power, temperature, and pressure of the plasma. A selectivity of higher than one indicates that the trenches in a silicon hard stamp 219 are deeper than the trenches in the resist after etching. The selectivity can be tailored by changing the plasma parameters to change the depth of the trenches. After the dry plasma etching, the resist is removed to leave a nano-grid of etched trenches in the hard substrate. The stamp may then be surface treated with monolayer anti-adhesion layers (such as silane), O₂ plasma, or wet or dry oxidizing processes to facilitate the demolding process in the subsequent replication steps.

The patterned mold surface 220 is contacted with a resin layer of the replica mold 222, the resin layer at least partially conforming to the mesh of ridges and/or trenches of the patterned mold surface 220 (204).

In an example process, NIL is used to copy the patterned mold surface 220 from the hard stamp 219 onto the replica mold 222. The replica mold 222 substrate may be flexible (e.g., but not limited to, polyethylene terephthalate (PET)) or hard (e.g., but not limited to, glass) depending on the upscaling process steps. Both R2P and P2P NIL processes may be employed to copy the patterned mold surface 220 from the hard stamp 219 onto the replica mold 222, be it flexible or hard. A photopolymer or thermoplastic curable resin is used to implement the replication process. If photopolymer, the resin can be cured using a specific-wavelength illumination such as UV light. If thermoplastic, the resin may be cured thermally at a high enough temperature that does not deform the replica mold 222 substrate.

In a P2P process, uncured resin is coated onto the replica mold 222 substrate to a desired thickness (e.g., but not limited to, in a range from about 1 micron to about 10 microns). The replica mold 222 is contacted with the hard stamp 219 and mechanical pressure is applied. In some implementations, a vacuum is applied to remove air bubbles at the contact surface of the uncured resin and hard stamp 219 and enhance the effectiveness of the mechanical pressure. The above molding process can be done in atmospheric pressure too; however, the mechanical pressure is used to ensure the resin and Master are in full contact.

In an R2P process, the replica mold 222 substrate may be mounted on a roller. The resin will be dispensed onto the hard stamp 219 and the roller comes in contact with the resin dispensed on the hard stamp 219. Upon rotation of the roller with controlled mechanical pressure, the resin will be pressed into the patterned mold surface 220 of the hard stamp 219.

The resin layer is at least partially cured when it is in contact with the patterned mold surface 220 (206). In a P2P process, in-situ thermal or photocuring is performed to crosslink the resin while mechanical pressure is applied. In an R2P process, the resin is partially cured to slightly harden the contacted resin and allows for a subsequent demolding without damaging the mesh grid 224 in the partially cured resin. The replica mold 222 is exposed to UV light or elevated temperatures to be fully cured and hardened after separating the hard stamp 219 and the replica mold 222. An in-situ full curing of the replica mold 222 resin while the mechanical pressure being applied is also possible. Similar to the P2P method, presence of an anti-adhesion monolayer or oxide layer on the stamp reduces the adhesion of the resin to the stamp in the demolding step.

In an NIL process, fidelity is defined as the similarity of imprinted mesh grid 224 to the original structures of the patterned mold surface 220 on the hard stamp 219 in terms of size and dimensions. The fidelity of the copied nanoimprinted mesh grid 224 in the replica mold 222 to the trenches or ridges in the hard stamp 219 depends on a few factors such as shrinkage of the resin during the crosslinking process. A low-shrinkage resin may be used to enhance the replication fidelity. This low-shrinkage resin in one example has a shrinkage change (percent volume change) between two percent and five percent.

The aspect ratio of a trench is defined as the ratio between the depth and width of the trenches (e.g., the height of the elevated structures 108 and the width of the trenches 110 of FIG. 1). Preserving the fidelity of high-aspect-ratio imprinted mesh grid 224 uses higher mechanical pressure and less viscous resins which can form into the details of the mesh grid 224 morphology. The aspect ratio determines the feasibility of the nanoimprinting process as described herein.

The polarity of the mesh grid 224 of the replica mold 222 is inverted compared to the patterned mold surface 220 of the hard stamp 219 which means that ridges in the patterned mold surface 220 create trenches in the replica mold 222 and vice versa. To produce a replica mold 222 that has the same polarity as the stamp, an even number of replications are performed. The number of child ‘generations’ from the hard stamp 219 is determined depending on the targeted polarity of the final electromagnetic wave director. Each generation has a lower fidelity to the original hard stamp 219; thus, the number of generations should be minimized based on the polarity of the final wave director.

The cured resin layer of the replica mold 222 is demolded from the patterned mold surface 220 to provide a layer of cured resin, wherein the layer of cured resin comprises an embossed mesh grid 224 comprising trenches and/or ridges that respectively correspond to the ridges and/or trenches of the patterned mold surface 220 (208).

A ‘place and repeat’ process is employed to upscale the imprinted mesh grid 224 to a larger footprint than the wafer-scale replica mold 222. This process replicates a smaller mold into several positionally aligned copies on a single larger mold. A large recombined mold 226 substrate having dimensions in a range from about 0.5 meter to about 2 meters and made of a flexible polymer (e.g., but not limited to, PET), or a rigid substrate (e.g., but not limited to, glass), is imprinted. In the ‘place’ step, resin is dispensed onto the recombined mold 226 substrate, and the replica mold 222 is contacted with the dispensed resin in a P2P or a R2P setup. The resin may be partially (soft) cured or fully (hard) cured during contact.

Molding and demolding occurs as in the ‘mold production’ step and are applied to repeatedly copy imprints 228 of the replica mold 222 onto the recombined mold 226 substrate. The imprinting process is repeated to populate the surface of the recombined mold 226 with as many imprints 228 of the mesh grid 224 as desired. Some examples of the imprinting process include using a hard cure step after the entire surface area of the recombined mold 226 is filled with imprints 228 depending on the curing time during the molding step. The recombined mold 226 with imprints 228 is then used for producing a working mold.

Similar considerations as in the recombined mold 226 production step are taken to control the shrinkage and maintain the fidelity of copied mesh grid 224:

In some examples, the mold 226 is surface treated with anti-adhesion monolayers, e.g., but not limited to, silane, to reduce the adhesion and facilitate the separation during the demolding process.

In some examples, a low-shrinkage (2%) and less viscous resin is used to preserve the fidelity.

In some examples, the polarity of the imprints in the recombined mold 226 alternates depending on the number of generations made between the recombined mold 226 and the original hard stamp 219.

In some examples, further cleaning processes are applied to clean the recombined mold 226. The cleaning agents are selected to be inert to the cured resin and thus the imprinted patterns. The recombined mold 226 is surface treated to facilitate the proceeding replication steps, including demolding steps.

In some examples, the imprints 228 have a gap between individual imprints 228 which is controlled by discrete alignment during the ‘repeat’ step. In the latter case, the gap can be smaller than what is resolvable by the unaided human eye (e.g., but not limited to, less than about 30 microns) to prevent the gap being visible. Additionally or alternatively, the imprints 228 partially overlap neighboring imprints 228 depending on the application and the final product. In general, some imprints 228 can be separated by a gap, while others are overlapped.

In some examples, the recombined mold 226 is converted into a flexible polymeric or metallic working mold 230 to be used in an industrial-scale R2R or R2P process. In this case, a working mold 230 is produced. In case of the polymeric working mold 230, the recombined mold 226 may be copied onto a flexible polymeric working mold 230 (e.g., but not limited to, polydimethylsiloxane (PDMS)) by direct copying in a R2P process.

If the recombined mold 226 is rigid, a P2P process is used to create the working mold 230. In the case of a metallic working mold 230, electroforming is utilized to produce the working mold 230. The embossed mesh grid of the working mold 230 is metallized to provide a metallized mesh grid having a layer of conductive material on a top surface of the elevated structures and trenches of the embossed mesh grid (210).

In an example, a single thin film (e.g., but not limited, a thickness in a range from about 50 to about 100 nm) of conductive material (e.g., but not limited to, silver or nickel) is deposited onto the recombined mold 226 using spray coating, sputtering physical vapor deposition, or by placing the recombined mold 226 in a metallization bath, or by metal-spaying the recombined mold 226.

A thin film of conductive metal, called a seed layer, is then conformally coated on the surface of recombined mold 226, covering all the sidewalls of the mesh grid 224 of each imprint 228 This ensures that the mesh grid 224 will be replicated with a high fidelity onto the seed layer and having with an inverted polarity with respect to the recombined mold 226. The seed layer is provided in order to facilitate depositing a thin metal layer that promotes the subsequent electroforming process. Without this thin layer, the patterned resin is not conductive and cannot be electroplated. It can be formed on the surface of the mold by vacuum (metal) deposition, spraying, or a metal bath process. It can be vacuum (metal) deposition, spraying, or metal bath process

The recombined resin mold 226 (on the PET substrate) is “metallized” with a thin metal layer to initiate electroforming, and then the entire stack is placed into an electroforming bath to grow thick layer of conductive metal (e.g., but not limited to, nickel) to a thickness in a range from about 10 to about 30 microns and has enough mechanical endurance to be installed on the R2R or R2P imprinting roller 232 and imprint as many copies as possible. The thick metallized copy of the recombined mold 226 is then mechanically separated from the recombined mold 226 to produce a metal tooling. This is a conversion step similar to the mold production step, but at larger dimensions, therefore is not shown in FIG. 2B.

The working mold 230 is mounted onto a R2R (shown in FIG. 2B), or R2P (not shown), nanoimprint lithography setup equipped with rotating rollers, including the mold roller 232, impression roller 234, and anilox roller (not shown). The anilox roller determines the thickness of a dispensed resin, which can also be fine-tuned using doctor blade. In such a setup, a length of a transparent flexible substrate 236 (e.g., but not limited to, PET) will run through the imprinting line and copies of the patterns embedded in the working mold 230 will be imprinted onto the resin dispensed on the flexible substrate 236. In many examples, the length can be tens, hundreds, or thousands of meters of substrate. Accordingly, the shim (working mold/tooling) is roll-mounted onto the printing roller. The anilox roller fine tunes the resin thickness that goes on the PET. The Nip roller then applies pressure on the PET substrate against the shim installed on the printing roller.

The metallized metallic working mold 230 is contacted to a second resin layer being supported by a substrate (212). In an example, the working mold 230 is flexible enough to bend onto the mold roller 232. The impression roller 234 brings the resin-coated flexible substrate 236 in contact with the working mold 230 installed on the mold roller 232. UV light is applied to crosslink the resin once the array on the working mold 230 is embossed onto the uncured resin on the substrate 236. This way, copies of the nano-grid imprint 228 are embossed into the resin on the roll substrate 236 to create a nano-grid 238. All shrinkage and fidelity considerations discussed above are applicable to this step.

The resin on the substrate 236 is cured while it is in contact with the metallic working mold 230 to create a cured resin layer (216). Some examples of the resin photosensitive resins, which are cured with UV radiation, or thermal-sensitive resins, which are cured by exposure to thermal radiation (e.g., heat, or IR radiation).

The cured resin on the substrate 236 is demolded from the metallic working mold 230 to remove the conductive material cap from the top surface of the elevated structures (218). The conductive material in the trenches remain. Depending on the polarity of the metallic working mold 230, either the metallic working mold 230 having the caps removed, or the resin—coated flexible substrate 236 having conductive material in the trenches, provides the nano-grid structure 100.

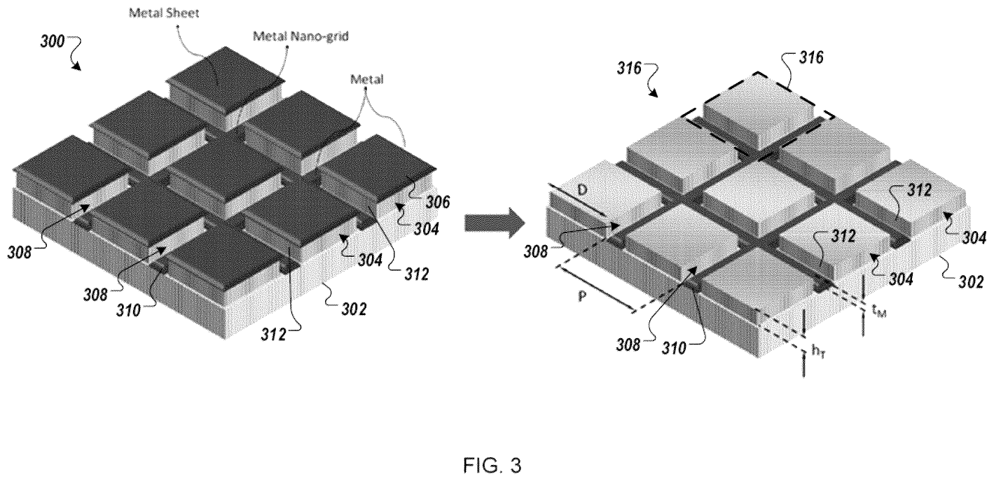

The substrate 236 roll (or, alternatively, plate material) produced in the process of FIG. 2B is functionalized by depositing a thin layer of a conductive metal, or alternatively, printing a layer of conductive ink onto the resin nano-grid 238. A perspective view of the functionalized nano-gird device 300 after metallization or printing is shown in the left panel of FIG. 3. The device 300 includes an array of structures 304 extending from a substrate 302. Each structure 304 has sidewalls 308 which define trenches 308 separating the structures 304. A grid 310 of conductive material is on a floor of the trenches 308 and each structure 304 is capped in a sheet 306 of the same conductive material.

In case of printing, the viscosity, wettability, and adhesion of the conductive material (e.g., but not limited to, conductive ink) with the trench 308 and sidewalls 312 and floor, e.g., bottom surface of the trench, l determines if the ink reaches and adheres to the floor of the trench 308. This functionalized nano-grid device 300 is composed of two layers: the sheet 306 at the top of each structure 304 and the nano-grid 310 at the bottom of the trenches 308. In the case where the imprinted resin nano-grid 238 embeds ridges, instead of trenches, the position of conductive sheet 206 and conductive grid 310 are switched. The conductive sheet 306 layer is removed and the conductive nano-grid 310 layer that is optically transparent and provides electromagnetic wave directing remains to create the director device 316 in the right panel to be utilized for applications disclosed herein.

The director device 316 including a periodic nano-grid 310 example with periodicity P, between structures 304 having a width of D, and a height of h_{T} is shown in the right panel of FIG. 3. The periodicity is in a range from about 5 microns and few hundred microns (e.g., but not limited to, in a range from about 5 microns to about 300 microns). The metallic nano-grid 310 is shown as being deposited to a thickness of 5 to 500 microns. Other specificities regarding D, h_{T}, and t_{M} are given herein. If a vacuum deposited metal is used: 50 nm to 500 nm, whereas if conductive printed ink is used, 100 nm to 5 microns, depending on the size of trenches. For the square array of the nano-grid device 300, a unit cell is defined as the features encompassed by a one period square. Unit cell 316 encompassing one structure 304 and a portion of the nano-grid 310 along two sidewalls 312 in the right image of FIG. 3.

The polarity of the imprinted nano-grid determines a duty cycle for the unit cell which are herein termed ‘ridges’ or ‘trenches’ as shown in FIG. 4, top and bottom, respectively. As used herein, a duty cycle is defined as the ratio between a width of the elevated structures and a width of the trenches of the grid 102. In one example, a duty cycle of 20% indicates that a width of the elevated structures is about 20% of the periodicity of the grid 102 while the trenches are about 80% of the periodicity. A ‘ridge’ example device 400 and a ‘trench’ example device 414 is shown having elevated structures 404 and trenches 402 imprinted in a base resin layer 412. The elevated structures 404 and the trenches 402 have deposited conductive material shown as caps 408 on the structures 404 and sheets 410 in the trenches 402. Broadly, the elevated structures 404 of the ‘ridges’ example have a smaller width, D1, than the trenches 402, while the elevated structures 404 of the ‘trenches’ example have a larger width, D2, than the trenches 402.

In the example case of ‘ridges’, e.g., elevated structures wider than trenches, directional physical vapour deposition (DPVD) (e.g., but not limited to, such as thermal or electron beam deposition) covers the bottom surface 418 of the trenches 402 and the top surface 306 of the elevated structures 404 of the nano-grid device 400 with the conductive material. The conductive material does not cover the sidewalls 420. Deposition (or printing) methods which coat the conductive material on the sidewalls 420 are not suitable for the fabrication method disclosed here.

The cap 408 of conductive material on top surface 406 of the elevated structures 404 grows vertically and, to a lesser extent (normally <50% of the vertical thickness deposited on the surface—this depends on the directionality (collimation) of the deposition process), laterally. This effect creates a portion of the cap 408 which extends partially over, e.g., overhangs, the trenches 402 adjacent the associated elevated structure 404. The overhanging portion of the cap 408 provides an anchor point to mechanically lift the cap 408 from top surface 306 of the elevated structures 404. In this case, the cap 408 provides a conductive nano-grid in the resin layer used to remove the cap 408 usable in the devices described herein.

An alternative polarity is the exemplary ‘trench’ geometry in which the structures 404 are wider than the trenches 402, shown in the bottom image of FIG. 4. In this example, the device 416 unit cell encompasses elevated structures 404 having a larger width, D2, than the trenches 402. In this case, the overhanging portion (not shown due to scale) of the cap 408 provides a mechanical leverage point to detach the cap 408 from the associated structure 404. The conductive material in the trenches 402, e.g., the sheets 410, provides a conductive nano-grid in the base resin layer 412 for the above applications.

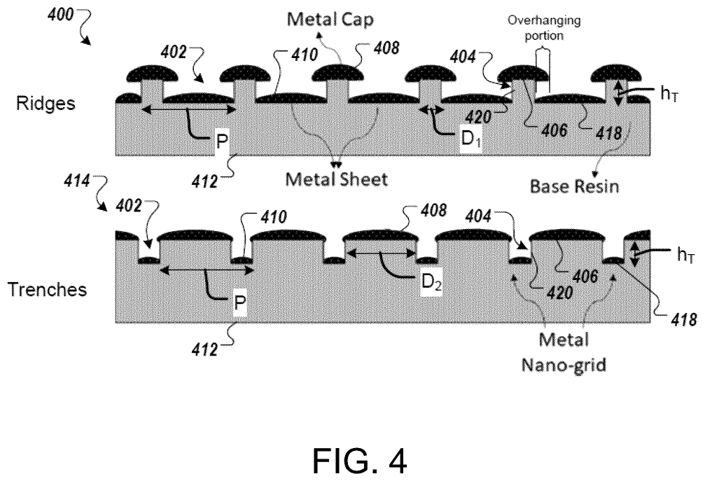

FIG. 5 shows the peeling mechanism used to remove the caps 408 in the ‘ridge’ embodiment of FIG. 4. In this method, an encapsulating resin is laminated onto the conductive nano-grid pattern shown in FIG. 3, left panel. The lamination process may be similar to the molding process described earlier in FIG. 1. In the next step, the cap conductive layer is peeled by applying an uplifting mechanical pressure leading to a conductive nano-grid pattern similar to the embodiment of FIG. 3, right panel.

A base resin 402 (which can be dispensed on a flexible (e.g., but not limited to, PET) substrate, not shown) is nanoimprinted from the recombined mold 516 (which can be provided by the recombined mold 226 described herein) as shown in Step 1. Minimal curing (e.g., soft curing) of the base resin 402, which causes weak or a smaller number of crosslink bonds, can help later in the nano-peeling step: in one example, a thin layer of the minimally cured resin is removed along with the separated metal cap layer, or, additionally or alternatively, the adhesion of the minimally cured resin to the metal cap layer is poor after deposition. Minimal curing limits the cross-linking and oxidation of the surface reducing surface energy, and facilitates molecular re-organization of the resin 402 to expose the lowest surface energy moieties, further reducing the adhesive forces at that interface to less than that of the encapsulating resin, which facilitates the separation of the metal cap layer upon application of a mechanical force.

This “surface energy” represents the amount of excess binding energy at a surface. In general, as surface energy increases, the adhesion to anything on the surface increases. Thus to facilitate selective removal of metal from the surface, the surface energy was tuned/reduced. Oxidation, a by-product of UV curing, generally increases the surface energy of organics/polymers.

A conductive material is disposed as described herein resulting in the ‘ridge’ example device 400 having the base resin 412 with structures 404 having caps 408 and trenches 402 with sheets 410 shown in Step 2.

An encapsulating/lift-off resin 520 to separate the conductive cap 408 from the structures 404, is dispensed uniformly onto a flexible substrate (e.g., but not limited to, PET) and contacted with the top of the device 400, encapsulating the conductive caps 408 on top of the structures 404 and shown in Step 3. The lift-off resin 520 is pressed against the device 400 to fill in the trenches 402 thereby contacting the sheets 410 and enclosing details of the structures 404 on the base resin 412 and the conductive materials. The mechanical pressure is exerted to establish physical contact and adjusted to improve the replication fidelity. Improving replication fidelity is important in this context because the stamp is designed based on photonic modeling and the closer the dimensions of the final product are to the dimensions in the stamp, the better the optical characteristics that will be obtained.

Although the fidelity loss across generations can be compensated for if the loss in each replication step is exactly known, the higher the replication fidelity, the more predictable the end result is.

In an example, the mechanical pressure is applied synchronous with crosslinking (hard cure) of the lift-off layer 520. This includes exposure to a UV lamp or LED in case of a photopolymer resin, or a thermal source in case of a thermoplastic resin. In further examples, the crosslinking of the lift-off resin 520 is fine-tuned, in terms of power and time, to optimize the robustness of the cured lift-off resin in the subsequent peeling step (e.g., step 4), and also to optimize the adhesion of the lift-off resin to the conductive caps 408. Cross-linking of the lift-off resin causes hardiness and adhesive energy difference in the subsequent peeling step.

In the example of using a photopolymer lift-off resin, the direction of applied UV exposure depends on the UV transparency of the applied conductive materials of the caps 408 and the sheets 410. For example, the penetration depth of UV light in silver thin film is a few hundred nanometers. In an example of the ridge embodiment, nano-peeling throughput (defined as the ratio between the effective nano-peeled area and the effective intact area) is increased by exposing the stacked device 400 and encapsulating resin 520 (e.g., the arrangement shown in Step 3) with the base resin 412 facing the light source.

The adhesion of five interfaces and the forces applied to the conductive layer at these interfaces is shown in the inset of FIG. 5. These interfaces and forces determine the nano-peeling throughput in the following nonlimiting example:

The base resin 412 is minimally crosslinked in Step 1, therefore additional light exposure hard cures the base resin 412 and increases the adhesion of the base resin 412 to the conductive caps 408 and sheets 410 at the S1 and S2 interfaces.

The lift-off resin 520 adjacent to the ridge area S3 receives sufficient light exposure to facilitate hard curing of the lift-off resin 520 once the exposure time is long enough (e.g., in one example but not limited to, about 30 seconds to about 120 seconds at about 40000 to about 60000 Lux exposure under a mercury UV lamp). The adhesion of the lift-off resin 520 to the overhanging portion of the conductive cap 408 at location S3 may be less than or comparable to S2 depending on the cure time of the lift-off resin 520; a lift-off resin 520 with a shorter curing time than the base resin 412 is desirable here.

The scattered light in the lift-off resin 520 facilitates increased crosslinking of the lift-off resin 520. The lift-off resin 520 contacting the conductive caps 408 and sheets 410 at S4 and S5 interfaces receives a small portion of scattered light in the example of the conductive caps 408 and sheets 410 are thick enough to be opaque to the curing light and establishes a weaker adhesion to the conductive caps 408 and sheets 410 compared to S1, S2, and S3. One example of such is >30 nm of PVD-deposited silver thin film for UVA exposure light.

In the ‘ridge’ example device 400 where the duty cycle is at or less than about 20%), the adhesion of the lift off resin 520 to the conductive cap 408 at S4 is larger than its adhesion to the conductive sheet 410 at S5, because the stray light received underneath the sheet 410 becomes weaker with increasing distance from the trench 402 opening.

An upward mechanical pressure is applied by uplifting the lift-off resin 520 at Step 4. In many examples, the thickness of the lift-off resin 520 is similar to the thickness of the base resin 412. The upward force (e.g., away from the base resin layer 412) applied by the lift-off resin 520 onto the conductive caps 408 initiates the peeling process if the lift-off resin 520 fully encapsulates the swollen corners (the overhanging portion at S3) of the conductive caps 408 and establishes an adhesion bond with the caps 408 at S3 and S4. The total force applied at S3 and S4 is larger than the total adhesion force the base resin 412 applies to the cap 408 at S2. On the other hand, the adhesion force applied by the base resin 412 to the sheets 410 at S1 may be greater than the adhesion force applied onto the sheets 410 at S5 which leads to the sheets 410 staying on the base resin 412 without separation. In this way, the caps 408 are embedded in the lift-off resin 520 and lifted off the structures 404. Thus, the cap 408 embedded in the lift-off resin 520 form a transparent conductive nano-grid 528 for the applications explained herein. Optionally, the conductive nano-grid 528 may be laminated using another resin for protection purposes.

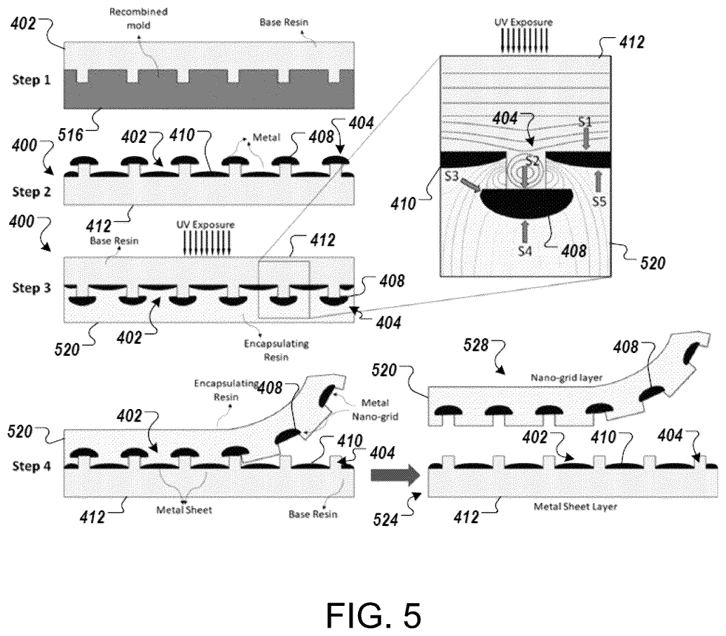

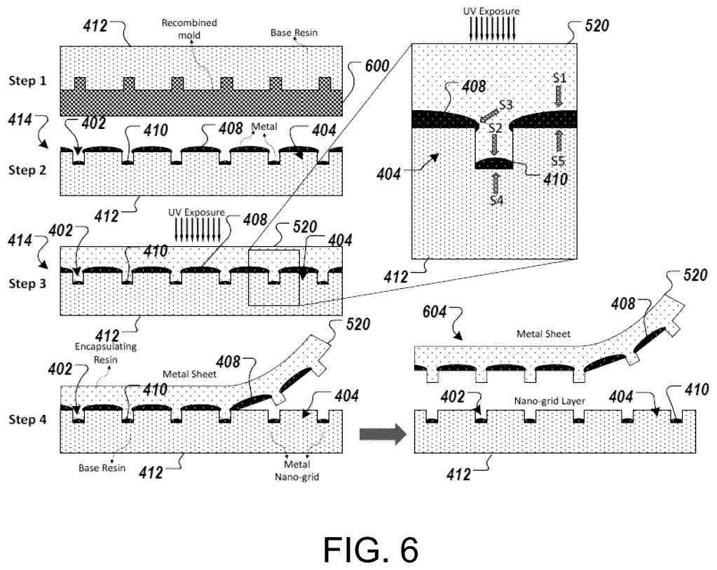

The nano-peeling mechanism of the ‘trench’ example device 414 is outlined in FIG. 6. The nano-peeling mechanism is similar to the one explained in FIG. 5. Similar steps and details are not repeated here to avoid redundancy. In some examples, the trench configuration is favoured in high volume production because of a higher throughput in general: in nano-peeling of the ‘ridge’ example device 400, the transferred caps 408 that undergoes separation with the lift-off resin 520 form the conductive nano-grid 528 with a smaller linewidth compared to the sheets 410. In the nano-peeling of the ‘trench’ example device 414 embodiment, however, the conductive sheets 410 which form the nano-grid remain intact in the base resin 412.

In the molding and nanoimprinting process, the steps performed in nano-peeling of the conductive nano-grid in the trench configuration are depicted in FIG. 6.

The base resin 412 is dispensed on a flexible substrate and nanoimprinted from the recombined mold 600 in Step 1. Minimal curing (e.g., soft curing) of the base resin 412 aids in subsequent steps as explained in the Step 1 of FIG. 5.

The coating of the conductive caps 408 and sheets 410 is performed as described herein to create the ‘trench’ example device 414.

The lift-off resin 520 is dispensed uniformly onto a flexible substrate (such as PET) and comes in contact with the conductive bilayer, encapsulating the conductive sheets 410 on top of the base resin 412 in step 3. The lift-off resin 520 contacts the conductive caps 408 and sheets 410 of the underlaid base resin 412 and pressure is applied downward to fill in the pores and details of nanostructures in the base resin 412 and the conductive caps 408 and sheets 410.

A mechanical pressure is exerted to establish physical contact and is adjusted to improve the replication fidelity. In some examples, this mechanical pressure is applied synchronous to the crosslinking of the lift-off resin 520, which is triggered by a UV lamp or LED or thermal source. In many examples, the crosslinking of the lift-off resin 520 is fine-tuned, in terms of power and time, to optimize the robustness of the cured lift-off resin 520 in the following peeling step, and also to optimize the adhesion of the lift-off resin 520 to the conductive sheets 410.

In a case of using a photopolymer lift-off resin 520, the direction of applied UV exposure may be critical depending on the UV transparency of the applied conductive caps 408 and sheets 410. In some examples of the trench embodiment, nano-peeling throughput is increased by exposing the stack (e.g., lift-off resin 520 and device 414 in Step 3) with the lift-off resin 520 facing the light source. The adhesion of five interfaces and the forces applied to the conductive layer at these interfaces, shown inset of FIG. 6, determines the nano-peeling throughput in this embodiment:

The lift-off resin 520 undergoes a full curing cycle to improve the adhesion to the conductive caps 408 at interfaces S1 and S3. Improved adhesion at these interfaces is crucial for lifting the conductive caps 408, leaving a nano-grid layer of sheets 410 in the base resin 412 trenches 402. The adhesion of the lift-off resin 520 to the overhanging portion of the caps 408 at S3 triggers the removal of the caps 408 at this interface.

Extended curing increases the adhesion to the sheets 410 in the trenches 402 at S2. However, the lack of a mechanical anchor point impedes peeling of the sheets 410 within trenches 402. Said another way, the sheets 410 do not have an overhanging portion to provide a mechanical peeling anchor, such as that of the cap 408 at S3.

Assuming UV-opaque conductive caps 408 and sheets 410, soft curing of the base resin 412 in Step 1, and a duty cycle of greater than about 20%, the base resin 412 receives a higher dose of light exposure in the exposure step at the S4 interface compared to S5. In the ridge configuration, the duty cycle of ridges is preferably smaller than 20%, considering that the periodicity may be large (a few hundreds of microns) and the ridge could be small (smaller than 20%).

Since the base resin 412 is soft cured, the extra exposure received in the exposure helps improve the adhesion bond at S4. The adhesion bond at S5 is the weakest. An upward mechanical pressure is applied by uplifting the lift-off resin 520. The thickness of the lift-off resin 520 may be similar to that of the base resin 412. In this ‘nano-peeling’ step, the upward force applied by the lift-off resin 520 onto the conductive caps 408 initiates the peeling process if the lift-off resin 520 fully encapsulates the overhanging corners of the conductive caps 408 and establishes an adhesion bond at S1 and S3, so that the total force applied to the caps 408 at S1 and S3 is larger than the adhesion force the base resin 412 applies to the caps 408 at S5. On the other hand, the adhesion force applied by the base resin 412 to the sheets 410 at S4 is greater than the adhesion force applied at S2 based on the assumptions above, which leads to the sheets 410 staying on the base resin 412 without separation. This way, the caps 408 are lifted off while embedded in the lift-off resin 520, leaving a transparent conductive nano-grid of sheets 410 in the base resin 412 suited for the applications explained above. Optionally, the conductive nano-grid of sheets 410 on the base resin layer 412 may be laminated using another resin for protection purposes.

FIG. 6B is a diagram that shows how the viscosity of the encapsulating layer may help an easier nano-peeling process when the base resin and the encapsulating resin have different viscosity and adhesion to the conductive layer. More specifically, a relatively low viscosity resin enables high-fidelity recombination of the grid pattern. A high viscosity encapsulating adhesive, however, does not reach to the bottom of trenches and leaves the nano-grid layer intact. In this case, the sheet layer will be removed in the nano-peeling step if: 1) The adhesion of the encapsulating resin to the conductive layer is larger than that of the base resin to the conductive layer. 2) The conductive layer does not wet the trench sidewalls, i.e., the nano-grid layer is not physically connected to the sheet layer. In a vacuum deposition process, this can be achieved by a directional/collimated metal deposition. The adhesive layer can be UV curable liquid or can be UV curable dry adhesive. This method mostly works with the trench embodiment where the surface area of the trench is comparatively small, and the size of the trenches impedes the high viscosity adhesive/dry adhesive to reach the bottom of the trench/metal grid.

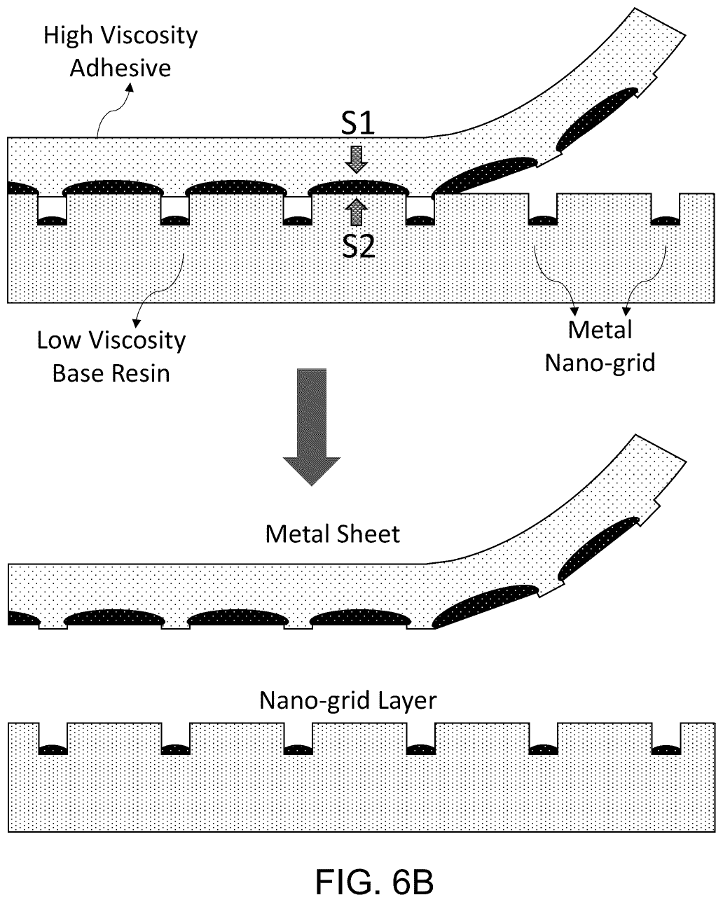

FIG. 7 shown an exemplary R2R production system for producing a transparent conductive nano-grid 528 which can provide the electromagnetic nano-grid structure 100. Assuming that the nano-grid 528 is produced using standard roll-to-roll processes explained above, it comes in contact with the lift-off resin 520 using the pressure rollers 1 and 2. The lift-off resin 520 is dispensed on the flexible roll carrier 702 (e.g., but not limited to, PET) with a certain thickness determined by using an anilox roller and doctor blade setup (not shown here). The lift-off resin 520 contacts with the nano-grid device between the pressure rollers 1 and 2. Examples of the nano-grid device are either the ‘ridge’ device 400 or the ‘trench’ device 414.

After the pressure is applied and the lift-off resin 520 has filled the trenches 402 and details of the device 400/414, light exposure is applied to fully cure the base resin layer 412 and the lift-off resin 520 layers (e.g., for one example, see the process description of FIG. 5). The light exposure in this configuration is applied from the base resin 412 side according to the process explained in FIG. 5 for the ‘ridge’ embodiment. A similar setup can be extended to the trench embodiment by appropriate positioning of the exposure light to expose the stack from the lift-off layer 520 side.

Once fully cured, the foil stack 706 of the device 400/414 and the lift-off layer 520 and substrate 702 reaches the demolding unit where demolding rollers 1 and 2 separate the carriers 704 and 702 and associated overlaid resin layers 412 and 520. The adhesion of resin to the carrier, e.g., base resin layer 412 to substrate 704 or lift-off layer 520 to substrate 702, is stronger than adhesion to the contacting resin layer, thus the demolding and separation occur at the interface between resins 412 and 520 and the conductive caps 408. The conductive nano-grid 528 embeds the conductive cap 408 in the resin 520 and suitable to provide the electromagnetic nano-grid structure 100 for the above applications. Optionally, the metal sheet web 708 is recycled to extract the conductive sheets 410 from the base resin layer 412 and reduce production costs.

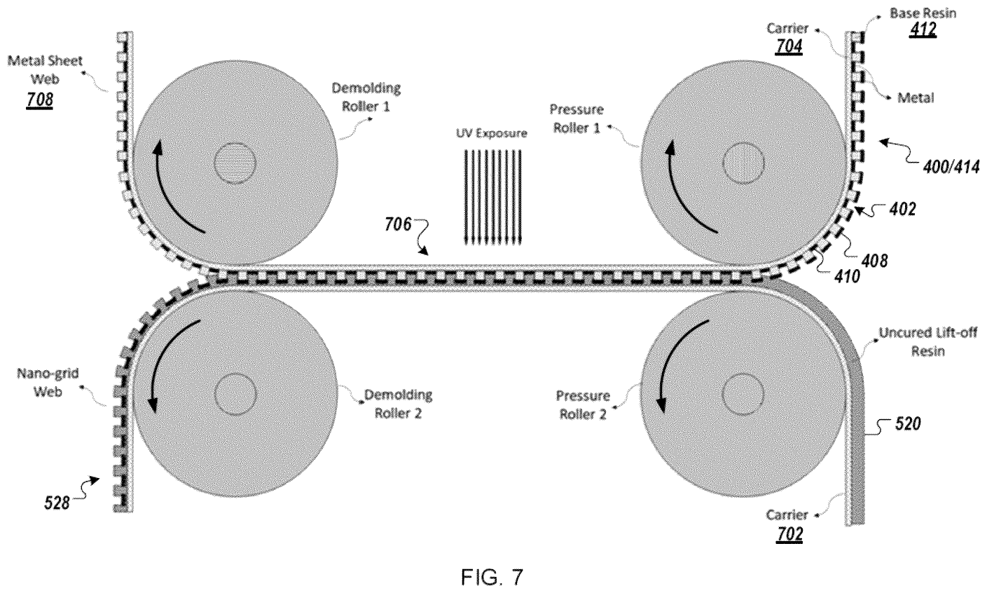

Assuming that an example nano-grid device 400/414 is produced on a carrier 704 using standard roll-to-roll processes explained above, an R2P nano-peeling setup in which the device 400/414 contacts the lift-off resin 520 using pressure roller 1 is shown in FIG. 8. The lift-off resin 520 is dispensed onto the solid or flexible carrier 802 (e.g., but not limited to, PET or glass) to a certain thickness that is tuned using a anilox roller and doctor blade setup. The role of anilox roller was described above. A doctor blade is a sharp blade that comes in contact with the resin layer dispensed on the PET (already controlled to some degree by the anilox roller in the previous step), and fine-tunes the thickness.

After the pressure is applied, and the lift-off resin 520 has filled the pores and details of the trenches 402 and structures 404, light exposure is applied to fully cure the base resin layer 412 and the lift-off resin 520 layers. The light exposure in this configuration is applied from the base resin 412 side according to the process explained in FIG. 5 for the ‘ridge’ embodiment. A similar setup can be extended to the ‘trench’ embodiment by appropriate positioning of the exposure light.

Once fully cured, the foil stack 804 will reach the demolding roller 1 at which point the base resin layer 412 separates from lift-off layer 520. The adhesion of the resin 412 to the carrier 702 is stronger than the adhesion to the conductive caps 408, thus the demolding and separation occur at the interface between the resins 412 and 520 and the conductive caps 408 and sheets 410. The nano-grid plate 806 embeds the transparent conductive nano-grid suitable to provide the electromagnetic nano-grid structure 100 for the above applications. Optionally, the metal sheets 410 are recycled to extract the conductive sheets 410 and reduce production costs.

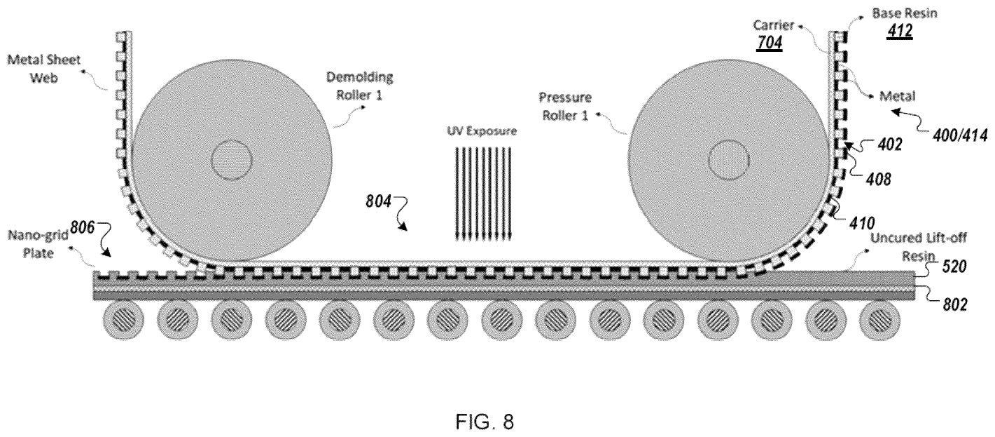

An image showing the transparency of an exemplary nano-grid structure wave director sample 900 made according to the method of the disclosure is shown against a window in FIG. 9. The wave director sample 900 incorporates all the elements of the exemplary electromagnetic nano-grid structure 100 in FIG. 1 excepting the protective layer. In one example, only the network of the conductive layer is considered to be the core (nano-grid) of the device. Although the surrounding resin is decisive and its refractive index impacts the overall performance/characteristics of the final product, the core component is the conductive layer.

Although not visible due to being transparent, the nanowires (e.g., which provide nanowires 104) are vacuum-deposited silver, 550 nm wide and 60 nm thick, embedded in 600 nm tall resin trenches (e.g., which provide trenches 110). The wave director sample 900 was made using an even generation copy of the original stamp, such as hard stamp 219, where the original stamp was a 6-inch silicon wafer embedding trenches of 570 nm width and 650 nm depth. The encapsulating resin, such as lift-off layer 520, peeled off conductive sheets of silver to leave a conductive nano-grid layer, as shown in the example process of FIG. 6. The wave director sample 900 had >90% throughput (e.g., throughput as used herein is defined as the ratio between the number of square metal sheets removed by the encapsulating resin to the initial number of square metal sheets before the nano-peeling process) and >90% connectivity between the wires (e.g., this is indicative of few breakages of the sheets 410 during peeling).

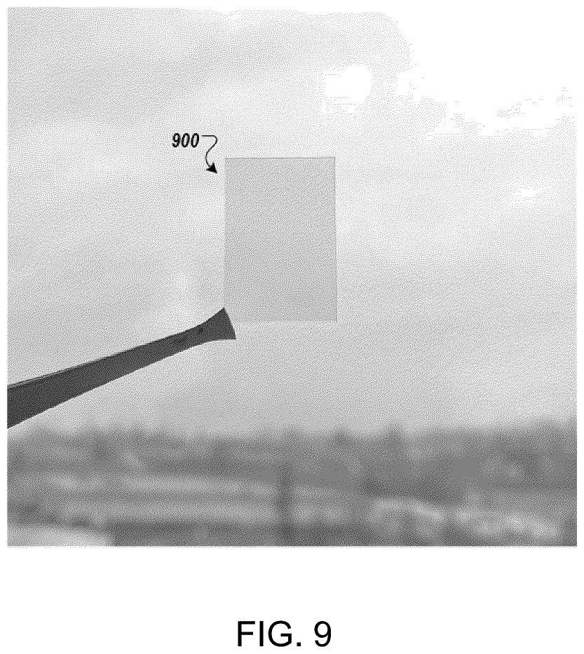

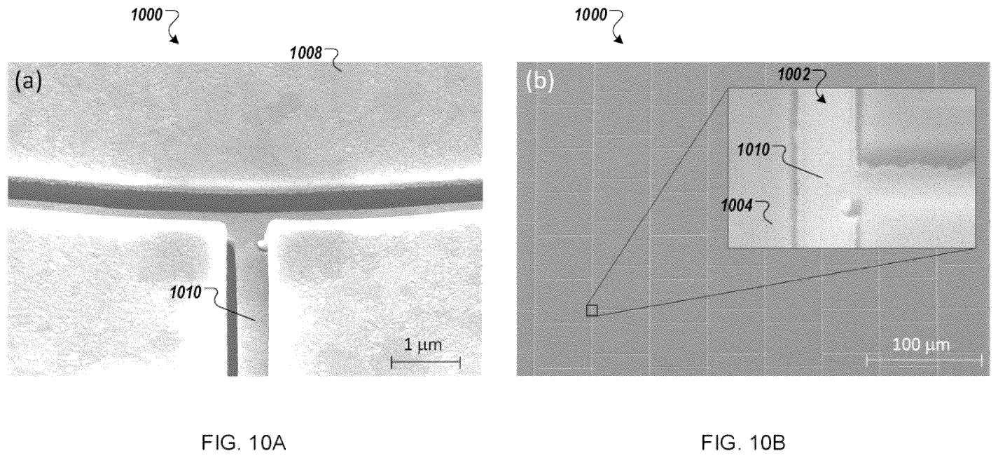

Exemplary scanning electron micrographs of a nano-grid structure 1000 made according to the method of the disclosure are shown in FIGS. 10A and 10B. A bi-layer of conductive material showing conductive caps 1008 and sheets 1010 before nano-peeling is shown in FIG. 10A and a nano-grid including a conductive material in the trenches 1002 of an exemplary nano-grid structure 1000 after the nano-peeling process is shown in FIG. 10B. The nanowire sheets 1010 are vacuum-deposited silver, 550 nm wide and 60 nm thick, embedded in 600 nm tall resin trenches 1002. The sample was made using an even generation copy of the original stamp, such as hard stamp 219, where the original stamp was a 6-inch silicon wafer embedding trenches of 570 nm width and 650 nm depth. The encapsulating resin, such as lift-off layer 520, peeled off conductive sheets of silver to leave a conductive nano-grid of conductive sheets 1010. The sample had >90% throughput and >90% connectivity between the wires.

In general, the composite materials described here can be useful in a variety of applications. In some examples, the nanostructured materials are useful as an electromagnetic wave director. The electromagnetic wave director can be a millimeter wave director for reflecting a signal emitted by at least one millimeter wave transmitter into at least one coverage zone lying outside the line of sight of the transmitter within which the signal can be detected by one or more millimeter wave receivers.

The director comprises a substrate supporting a diffractive element configured to diffract millimeter waves. The diffractive element is formed from a two-dimensional array of subwavelength nanowires formed into a resin layer on the substrate, such as the nano-grid structures disclosed herein. The diffractive element has a metasurface prescription for modifying the amplitude and phase of incident millimeter wavefronts on each subwavelength structure. The term “metasurface prescription” refers to the specification of optical parameters that determine the amplitude and phase of diffracted light, the important parameters being the spatial frequencies of diffracting features, dielectric constants, surface modulation, and birefringence. The millimeter wave director enables control over angular bandwidth and reflection. In further examples the millimeter wave director can operate in a transmission mode. In many examples, the apparatus comprises the diffracting elements formed from subwavelength structure and a back director sandwiching a spacer.

Although certain specific embodiments are described above for instructional purposes, the teachings of this patent document and are not limited to the specific embodiments described above. Accordingly, various modifications, adaptations, and combinations of various features of the described embodiments can be practiced without departing from the scope of the invention as set forth in the claims.

What is claimed is:

1. A patterned composite material, comprising:
a substrate comprising a layer of cured resin material having a network of elevated structures separated by trenches, the trenches having electrically conductive material disposed on a bottom surface and the elevated structures having electrically conductive material disposed on a top surface of the elevated structures such that a portion of the conductive material on the top surface of the elevated structures extends partially over the trenches; and
an uncured resin layer disposed to contact the electrically conductive material in the trenches and sidewalls of the elevated structures and enclose the electrically conductive material on the elevated structures.

2. The material of claim 1, wherein an aspect ratio of the trenches is in a range from 100:1 to 1:100.

3. The material of claim 1, wherein the substrate is optically transparent.

4. The material of claim 1, wherein the uncured resin layer is disposed to cover a portion of the layer of cured resin material.

5. The material of claim 1, wherein a duty cycle of the network of elevated structures and trenches is greater than 60% or less than 40%.

6. The material of claim 5, wherein a duty cycle of the network of elevated structures and trenches is greater than 80% or less than 20%.

7. The material of a claim 1, wherein the substrate is a flexible substrate.

8. The material of claim 1, wherein the uncured resin layer is disposed on a second substrate, the second substrate contacting the uncured resin layer on a side opposite the layer of cured resin material.

9. The material of claim 1, wherein the electrically conductive material comprises a metal, conductive ink, or semi-conductor.

10. The material of claim 9, wherein the semi-conductor comprises indium tin oxide.

11. A method for forming a patterned composite material, the method comprising:
providing a stamp comprising a patterned mold surface, the patterned mold surface comprising a network of elevated structures separated by trenches;
contacting the patterned mold surface with an uncured resin layer, the uncured resin layer at least partially conforming to the network;
curing the uncured resin layer when it is in contact with the patterned surface to form a cured resin layer;
demolding the cured resin layer from the patterned mold surface to provide a patterned cured resin layer, the patterned cured resin layer comprising an embossed pattern having a second network of elevated structures separated by trenches that corresponds to an inverse of the network of the patterned mold surface;
metallizing the embossed pattern to provide a metallized pattern having conductive material caps on a top surface of the elevated structures and conductive material sheets on a bottom surface of the trenches, a portion of the conductive material caps extending partially over the trenches;
contacting the metallized pattern with a second uncured resin layer, the second uncured resin layer at least partially conforming to the metallized pattern;
curing the second uncured resin layer while it is at least partially conformed with the metallized pattern to form a second cured resin layer;
demolding the second cured resin layer from the metallized pattern to remove the conductive material caps from the top surface of the elevated structures and provide the patterned composite material in the uncured resin material or the second cured resin material having conductive material sheets on the bottom surface of the trenches.

12. The method of claim 11, wherein the elevated structures or the trenches have a line width of about 10 microns or less.

13. The method of claim 11, wherein providing the stamp comprises forming the patterned mold surface on a stamp using electron beam lithography, or chemical or plasma etching.

14. The method of claim 11, wherein the contacting comprises a roll-to-roll, roll-to-plate, or a plate-to-plate printing process.

15. The method of claim 11, wherein the forming comprises a roll-to-roll printing process or a roll-to-plate printing process.

16. The method of claim 11, comprising disposing a layer of a protective material on the patterned composite material.

17. The method of claim 11, wherein curing the uncured resin layer comprises soft curing the uncured resin layer.

18. The method of claim 11, wherein curing comprises exposing the uncured resin layer, the second uncured resin layer, or both, to thermal or ultraviolet radiation.

19. The method of claim 11, wherein metallizing the embossed pattern comprises directional physical vapour deposition of the conductive material to provide the metallized pattern.

20. The method of claim 11, further comprising forming an electromagnetic wave director using the patterned composite material.
